(19) United States
(12) Patent Application Publication
(10) Pub. No.: US 2026/0308760 A1
(43) Pub. Date: Oct. 8, 2026

(54) THIN-FILM DEPOSITION APPARATUS AND METHOD

(71) Applicant: Picosun Oy, Espoo (FI)

(72) Inventors: Juhana KOSTAMO, Espoo (FI); Tom BLOMBERG, Espoo (FI); Mikko NÄSI, Tempe, AZ (US)

(21) Appl. No.: 19/176,260

(22) Filed: Apr. 11, 2025

(30) Foreign Application Priority Data
May 6, 2024 (FI) 20245558

(51) Int. Cl. C23C 16/455

(52) U.S. Cl. CPC C23C 16/45504; C23C 16/45544; C23C 16/45591

(57) ABSTRACT

A thin-film deposition (100) apparatus comprising, a reaction chamber (110) for accommodating a stack of substrates (120) arranged with their planar surfaces facing each other, a fluid distributor (150) for establishing a laminar fluid flow to propagate from a reaction chamber entrance (230) through the length of the reaction chamber (110) and between the substrate surfaces, wherein the fluid distributor (150) comprises an expansion region (210) configured to laterally expand reactant fluid flows (F1, F2) received from gas inlets (155a, 155b), and a cooler (160) coupled to the expansion region (210) and configured to control the temperature of the expansion region (210).

### TECHNICAL FIELD

The present disclosure generally relates to substrate processing equipment and associated methods. The disclosure relates particularly, though not exclusively, to a thin-film deposition apparatus comprising a fluid distributing device operable with sensitive precursors.

### BACKGROUND

This section illustrates useful background information without admission of any technique described herein representative of the state of the art.

Substrate processing methods can be used to deposit thin films onto substrates from a vapor phase. For instance, Atomic Layer Deposition (ALD) is a widely used technology for preparing thin films. ALD is based on alternating self-saturating surface reactions on a substrate, wherein different reactants (precursors) provided as chemical compounds or elements, in a nonreactive inert gaseous carrier in some implementations, are sequentially pulsed into a reaction space accommodating a substrate. Deposition of a reactant is typically followed by purging the substrate by inert gas. Precursor-purge cycles are repeated as many times as required for obtaining a film with a predetermined thickness.

Different kinds of vapor phase reactants can be used for surface deposition processes. The reactants may differ, for example, in stability and preferred reaction conditions which need to be considered for the surface deposition processes. Otherwise, reaction quality and reactant consumption may be negatively affected. For example, temperature sensitive precursors may decompose before reaching the reaction chamber or a substrate surface.

Therefore, a need exists in the field of substrate processing to assess these challenges related to the use of sensitive precursors.

### SUMMARY

It is an object of certain embodiments of the invention to provide an improved substrate processing apparatus and method optimized to address the challenges related to the use of temperature sensitive precursors or at least to provide an alternative solution to existing technology.

The appended claims define the scope of protection. Any examples and technical descriptions of apparatuses, products and/or methods in the description and/or drawings not covered by the claims are presented not as embodiments of the invention but as background art or examples useful for understanding the invention.

According to a first example aspect there is provided a method comprising a thin-film deposition apparatus comprising:
a reaction chamber for accommodating a stack of substrates arranged with their planar surfaces facing each other;
a fluid distributor for establishing a laminar fluid flow, by combining first reactant fluid flow and second fluid flow, to propagate from a reaction chamber entrance through the length of the reaction chamber and between the substrate surfaces, wherein the fluid distributor comprises an expansion region configured to laterally expand the reactant fluid flows before forming the laminar fluid flow; and
a cooler coupled to the expansion region and configured to control the temperature of the expansion region.

Advantageously, premature decomposing of temperature sensitive precursors of the reactant flows may be reduced. Further, temperature control of the reactant flows may be improved.

In certain embodiments, the thin-film deposition apparatus is an ALD apparatus. In certain embodiments, the reactant fluid flows comprise temperature sensitive precursor or precursors.

In certain embodiments, the cooler is attached to outer surface of the expansion region. Advantageously, maintenance of the cooler may be facilitated. Further, cooler components do not interfere with flow paths of the reactant flows.

In certain embodiments, the cooler comprises coolant liquid. In certain embodiments, the cooler comprises metal block thermal well. In certain embodiments, the cooler comprises a Peltier element. Advantageously, the cooler is not limited to a single cooler type but instead may be adapted to various types of thin-film deposition apparatuses and conditions.

In certain embodiments, the apparatus comprises a controller configured to control the temperature of the expansion region separately from the temperature of the reaction chamber. Advantageously, waste and undesired decomposition of temperature sensitive resources (of the reactant flows) may be reduced as they may be better protected from high processing temperatures during expansion and mixing before entering the reaction chamber. Further, more accurate temperature control within the apparatus may be enabled in general.

In certain embodiments, the expansion region comprises two opposite triangle-shaped spreader regions, wherefrom the respective fluid flows are directed towards the reaction chamber entrance as a combined flow through a throat of the fluid distributor. Advantageously, reactant flow spreading may be improved by the triangle-shaped spreader regions. Further, cooling of the expansion region may be improved through relatively large flat surfaces of triangle-shaped spreaders while enabling efficient reactant flow spreading.

In certain embodiments, each spreader region comprises a first flow surface area and a second surface area on the inner surfaces of the respective spreader regions, wherein the first flow surface area extends from a gas inlet connection of the respective spreader region towards a transition region of the fluid distributor following the shape of the spreader region, and wherein the second flow surface area is located downstream of the first flow surface area and extends from the end of the first flow surface area to the transition region.

In certain embodiments, the first flow surface area has a first surface roughness and the second flow surface area has a second surface roughness, and wherein the first surface roughness is lower than the second surface roughness. Advantageously, surface area enabling undesired physisorption near the gas inlets connections within the expansion regions may be minimized.

In certain embodiments, the fluid distributor comprises a thermal insulation arrangement between the expansion region and throat of the fluid distributor. In certain embodiments the thermal insulation arrangement is a gasket. Advantageously, temperature control of the fluid distributor separately from the reaction chamber may be improved.

In certain embodiments, the fluid distributor is configured to turn the flow direction of the reactant fluid flows from the spreader regions 90 degrees to redirect them towards the throat and reaction chamber entrance. Advantageously, mixing of the reactant fluid flows may be improved by the turning (curved) flow path within the fluid distributor.

In certain embodiments, the apparatus comprises comprising a vacuum chamber at least partially surrounding the reaction chamber and the fluid distributor. Advantageously, vacuum control of the reaction chamber may be improved. Further, risk of contamination may be reduced.

In certain embodiments, the inner side of the vacuum chamber facing the cooler located on an outer surface of the fluid distributor is free from heat reflector plates. Advantageously, cooling efficiency through radiation may be improved.

In certain embodiments, the cooler is attached to the vacuum chamber wall and connected to the expansion region via cooling means. Advantageously, the cooler may be adapted and attached to various kinds of fluid distributors and thin-film deposition apparatuses.

In certain embodiments, the apparatus comprises a thermal insulation arrangement located between the expansion region of the fluid distributor and the reaction chamber. Advantageously, precursors may be delivered through the fluid distributor at temperature that is lower than the processing temperature within the reaction chamber. Consequently, premature precursor decomposition within the fluid distributor may be minimized.

According to a second example aspect, there is provided a method for thin-film deposition, comprising:
loading a stack of substrates to a reaction chamber;
providing first reactant fluid flow and second reactant fluid flow to an expansion region of a fluid distributor upstream of a reaction chamber;
expanding said reactant fluid flows laterally within the expansion region;
controlling temperature of the expansion region and the reactant fluid flows within the expansion region by a cooler which is coupled to the expansion region; and
establishing a laminar fluid flow, by combining said reactant fluid flows, by the fluid distributor, to propagate from a reaction chamber entrance through the length of the reaction chamber and between the substrate surfaces for substrate processing.

In certain embodiments, the cooler is attached to outer surface of the expansion region. In certain embodiments, the cooler comprises coolant liquid. In certain embodiments, the cooler comprises metal block thermal well. In certain embodiments, the cooler comprises a Peltier element.

In certain embodiments, the method further comprises controlling the temperature of the expansion region separately from the temperature of the reaction chamber.

In certain embodiments, the reactant fluid flows comprise temperature sensitive precursor or precursors.

In certain embodiments, the method comprises processing the stack of substrates with alternating self-limiting surface reactions. In certain embodiments, the method comprises processing the stack of substrates with an ALD process.

Different non-binding example aspects and embodiments have been illustrated in the foregoing. The embodiments in the foregoing are used merely to explain selected aspects or steps that may be utilized in different implementations. Some embodiments may be presented only with reference to certain example aspects. It should be appreciated that corresponding embodiments may apply to other example aspects as well.

### BRIEF DESCRIPTION OF THE FIGURES

Some example embodiments will be described with reference to the accompanying figures, in which:

FIG. 1 schematically shows a cross-sectional side view of a thin-film deposition apparatus according to certain embodiments;

FIGS. 2a and 2b schematically show cross-sectional views of a thin-film deposition apparatus according to certain embodiments;

FIGS. 3a and 3b schematically show cross-sectional views of a thin-film deposition apparatus according to certain embodiments;

FIG. 4 schematically shows a cross-sectional view of a part of an expansion region according to certain embodiments;

FIGS. 5 and 6 show flow charts of methods according to certain embodiments; and

FIG. 7 schematically shows a thin-film deposition apparatus according to certain embodiments.

### DETAILED DESCRIPTION

In the following description, like reference signs denote like elements or steps.

Certain embodiments, described in more detail below, describe a thin-film deposition apparatus 100 comprising a reaction chamber 110 for accommodating a stack of substrates 120 arranged with their planar surfaces facing each other. In certain embodiments, the apparatus 100 comprises a fluid distributor 150 for establishing a laminar fluid flow LF propagating from the reaction chamber entrance 230 through the length of the reaction chamber 110 and between the substrate surfaces. In certain embodiments, the fluid distributor 150 is configured to form the laminar fluid flow LF by combining first (reactant) fluid flow F1 and second (reactant) fluid flow F2 within the fluid distributor 150. In certain embodiments, the fluid distributor 150 comprises an expansion region 210. In certain embodiments, the expansion region 210 is configured to expand reactant fluid flows F1, F2 laterally. In certain embodiments, the expansion region 210 is configured to expand fluid flows F1, F2 received from two gas inlets 155a, 155b to a width or height of the reaction chamber 110. In certain embodiments, the apparatus 100 comprises a cooler 160. In certain embodiments, the cooler 160 coupled to (the outer surface of) the expansion region 210. In certain embodiments, the cooler 160 is configured to control the temperature of the expansion region 210. In certain embodiments, the cooler 160 is configured to control the temperature of the expanding reactant fluid flows F1, F2 within the expansion region 210. In certain embodiments, the cooler 160 comprises coolant liquid. In certain embodiments, the cooler 160 comprises water-cooling. In certain embodiments, the cooler 160 comprises a metal block thermal well. In certain embodiments, the cooler 160 comprises Peltier element. The coolant liquid may be, for example, water or suitable oil.

In certain embodiments, the reactant fluid flows F1, F2 comprise temperature sensitive precursors.

The present disclosure relates to a substrate processing apparatus (thin-film deposition apparatus) 100 comprising laminar fluid flow reaction chamber. Laminar flow, or streamline flow, is defined, in the context of the present disclosure, as a flow void of turbulence (without turbulent velocity fluctuations). In a laminar flow, fluid layers/streams slide in parallel in an absence of vorticity, swirls or currents. The laminar flow constantly progresses to one direction, for instance from an entrance of a reaction chamber towards an exhaust outlet.

Lateral or vertical spreading or expansion of the lateral flow or deviation from the shortest linear path may occur as long as the flow constantly proceeds towards the predetermined direction. That is, the laminar flow comprises lateral spreading of fluid within the reaction chamber. Therefore, the laminar flow in the context of this application may curve but not return or flow backwards. For clarity, we note that the present invention should not be confused with any kind of venturi applications neither in terms of structural details nor with regard to functionality.

In the apparatus 100 described herewith, laminar flow is supported for both precursor fluid flow and for inert fluid flow, the latter occurring, in ALD, during purge periods, for example. Hence, the substrates 120 arranged in the substrate holder 123 encounter a laminar fluid flow LF inside the reaction chamber 110.

Embodiments according to the present disclosure relate to a substrate processing apparatus 100 and a method. Substrate processing apparatuses 100 and a flow chart for a method according to certain embodiments are shown in the accompanying figures. The substrate processing apparatuses 100 are configured to exploit principles of vapor-deposition based techniques. The method may be implemented for example in the presented apparatuses 100. In preferred embodiments, the substrate processing apparatus 100 is an ALD apparatus.

In ALD, at least one substrate 120 is typically exposed to temporally separated precursor pulses in a reaction vessel 110 to deposit material on the substrate surfaces by sequential self-saturating surface reactions. In the context of this application, the term ALD comprises all applicable ALD based techniques and any equivalent or closely related technologies, such as, for example the following ALD sub-types: MLD (Molecular Layer Deposition) plasma-assisted ALD, for example PEALD (Plasma Enhanced Atomic Layer Deposition) and photon-enhanced Atomic Layer Deposition (known also as flash enhanced ALD). Principles of ALD are known to the person skilled in the art.

In further embodiments, the substrate processing apparatus 100 may be applied to other deposition technologies, such as Physical Vapor Deposition (PVD) and for Plasma-Enhanced Chemical Vapor Deposition (PECVD) processes.

In certain embodiments, the substrate processing apparatus 100 is an atomic layer etching (ALE) apparatus.

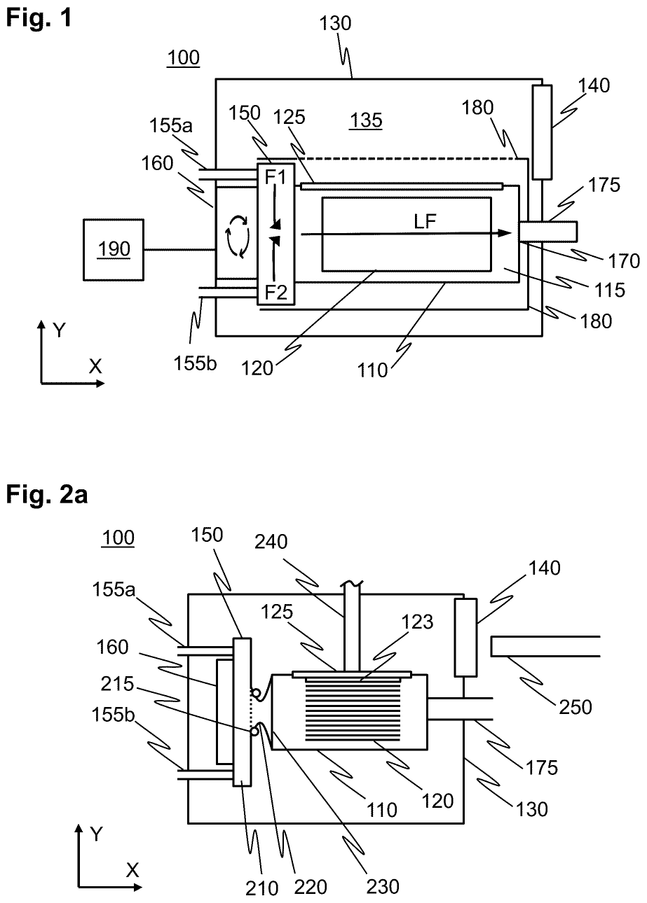

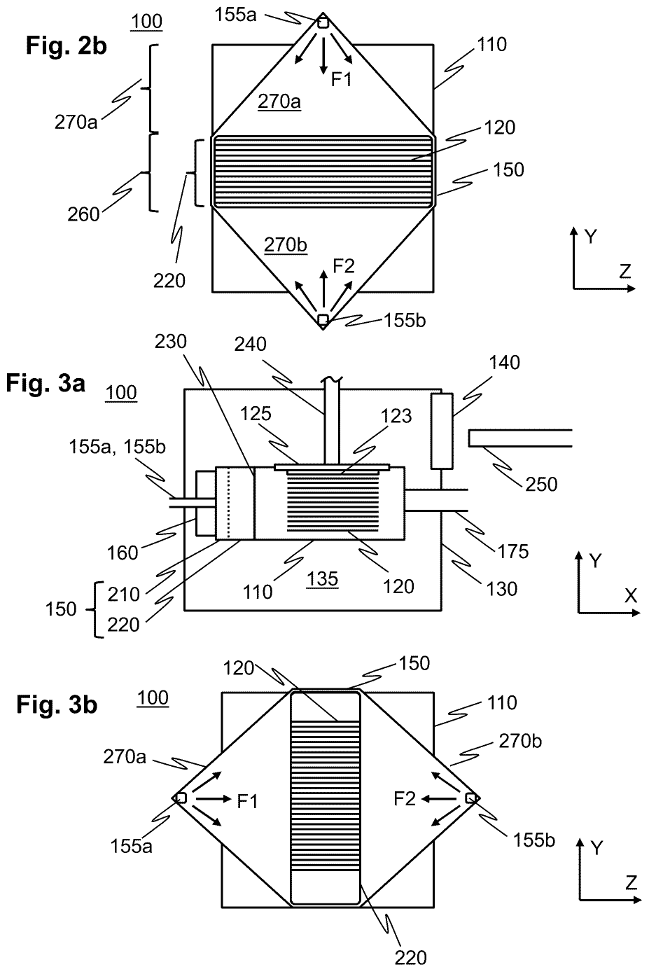

FIGS. 1-3b schematically show cross-sectional views of thin-film deposition apparatuses 100 according to certain embodiments. FIGS. 1-2b show the apparatuses 100 having a fluid distributor 150 in a vertical configuration. FIGS. 3a-3b show the apparatuses 100 having a fluid distributor 150 in a horizontal configuration. FIGS. 1, 2a and 3a are cross-sectional side-views of thin-film deposition apparatuses 100 according to certain embodiments. FIGS. 2b and 3b are cross-sectional front-views of the apparatuses 100 viewed from the direction of the fluid distributor 150 towards the reaction chamber 110 along the direction of laminar fluid flow LF (i.e. along X direction visible in FIGS. 1, 2a, and 3a) through the reaction chamber 110. In FIGS. 2b and 3b, substrates 120 within the reaction chamber 110 are visible through and behind a transition region 260 and a throat 220 of the fluid distributor 150. To ease the reader, a directional guide with X, Y, and Z axes is shown in FIGS. 1-4. Note that, for example, in FIG. 2a, the view direction is such that the Z direction is perpendicular to the page, whereas in FIG. 2b the X direction is perpendicular to the page and, thus, not visible in the respective figures.

The thin-film deposition apparatus 100 comprises a reaction chamber 110. The inside of the reaction chamber 110 defines a reaction volume 115. The reaction volume 115 extends from a reaction chamber entrance 230 to an exhaust outlet 170 and is further limited by inside walls of the reaction chamber 110 and a reaction chamber door 125.

The reaction chamber 110 is adapted to accommodate substrates 120 within the reaction volume 115. The substrates 120 may be, for example, circular wafers. In certain embodiments, the planar surfaces of the substrates 120 are aligned parallel to the direction of laminar fluid flow LF through the reaction chamber 110 (from the reaction chamber entrance 230 to the exhaust opening 170, i.e., parallel to the X direction visible in FIGS. 1, 2a, and 3a) when accommodated within the reaction chamber 110.

In certain embodiments, the reaction chamber 110 is configured to accommodate a stack of substrates 120. In certain embodiments, the reaction chamber 110 is shaped according to the shape of a substrate stack to accommodate the substrates 120. In certain embodiments, the substrates 120 are arranged in a stack with their planar surfaces facing each other. For example, horizontally aligned wafers 120 may be arranged into a vertical stack, and vice versa. The substrates 120 in the stack are spaced apart such that the laminar fluid flow LF (parallel to X direction visible in FIGS. 1, 2a, and 3a) may propagate through the stack between the substrate surfaces. The substrate spacing is dependent on the dimensions of a substrate holder 123. In certain embodiments, the substrate stack comprises up to 30 substrates 120.

In certain embodiments, the reaction chamber 110 comprises a door 125 for loading and unloading substrates 120 to and from the reaction volume 115. In FIGS. 1, 2a and 3a, the door is shown in the roof (top wall) of the reaction chamber 110. However, the door 125 may alternatively be in the bottom wall or a side wall of the reaction chamber 110 depending on the reaction chamber geometry. The door position may depend on the positioning of the reaction chamber entrance 230, exhaust opening 170 and a substrate transfer system 240 as well as the dimensions of the reaction chamber 110.

The door 125 is configured to seal the reaction volume 115 during substrate processing. In certain embodiments, the door is configured to seal the reaction volume 115 hermetically.

In certain embodiments, the door 125 is hinged. In certain embodiments, the door 125 is detachable from the reaction chamber 110. In certain embodiments, the door 125 is integrated to the substrate holder 123. In certain embodiments, the door 125 is integrated and configured to be movable with the substrate transfer system 240. In certain embodiments, the substrate transfer system 240 is configured to transfer the substrates or a stack of substrates 120 to and from the reaction volume 115.

The reaction chamber 110 comprises a reaction chamber entrance 230. Laminar fluid flow LF enters the reaction chamber 110 through the reaction chamber entrance 230. In certain embodiments, the reaction chamber 110 comprises only one reaction chamber entrance 230. That is, the reaction chamber entrance 230 is a single opening in certain embodiments. In certain embodiments, the width of the reaction chamber entrance 230 corresponds to the width of the reaction chamber 110. In certain embodiments, the height of the reaction chamber entrance 230 corresponds to the height of the reaction chamber 110. A fluid distributor 150 is connected to the reaction chamber 110 via the reaction chamber entrance 230.

In certain embodiments, the reaction chamber 110 comprises an exhaust opening 170. In certain embodiments, the exhaust opening 170 is in the reaction chamber wall opposite to the reaction chamber entrance 230. Advantageously, laminar flow conditions are improved as the laminar fluid flow LF has a direct path from the reaction chamber entrance 230 to the exhaust opening 170 through the substrates 120.

In certain embodiments, the reaction chamber 110 comprises exhaust line 175 connected to the exhaust opening 170. The laminar fluid flow LF propagating through the reaction chamber 110 is removed from the reaction volume 115 through the exhaust opening 170 and the exhaust line 175. In certain embodiments, the exhaust line 175 further comprises or is connected to a vacuum pump. Advantageously, fluid flow and removal from the reaction chamber 110 may be improved and efficiently controlled.

The apparatus 100 comprises a fluid distributor 150. The fluid distributor 150 comprises an expansion region 210 and a throat 220. For illustrative purposes, in FIGS. 2a and 3a, the expansion region 210 is separated from the throat 220 by a dashed line. Expansion region 210 refers to a structure of the fluid distributor 150 which causes fluid flows F1, F2 to expand within the fluid distributor 150. The fluid distributor 150 is located immediately upstream of the reaction chamber 110. The fluid distributor 150 is configured to establish the laminar fluid flow LF to and through the reaction volume 115. In certain embodiments, the fluid distributor 150 establishes a laminar fluid flow LF to propagate from the reaction chamber entrance 230 through the length of the reaction chamber 110 and between the substrate surfaces in the substrate stack within the reaction volume 115 (i.e. parallel to the X direction).

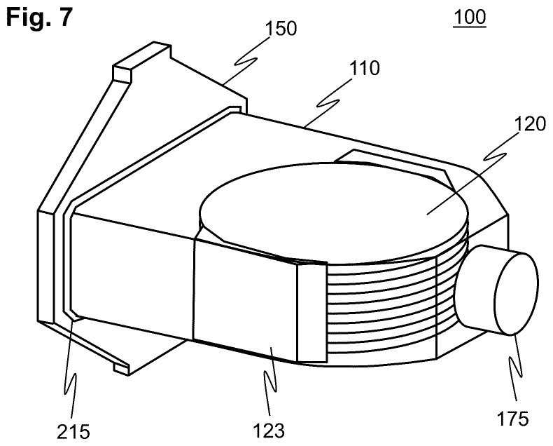

In certain embodiments, the apparatus 100 comprises a thermal insulation arrangement 215 located between the expansion region 210 of the fluid distributor 150 and the reaction chamber 110. In certain embodiments, the apparatus 100 comprises a thermal insulation arrangement 215 between the fluid distributor 150 and the reaction chamber 110. An exemplary thin-film deposition apparatus 100 comprising the thermal insulation arrangement 215 is schematically depicted in FIG. 7. In FIG. 7 the substrate stack within the reaction chamber 110 is also shown.

The thermal insulation arrangement 215 is configured to provide a thermal break between the expansion region 210 of the fluid distributor 150 and the reaction chamber 110 to prevent heat conduction from the reaction chamber 110 to (the expansion region 210 of) the fluid distributor 150. Therefore, the thermal insulation arrangement 215 is configured to operate as a barrier to prevent heat conduction from the conductive material(s), such as stainless steel or aluminium, and structures of the reaction chamber 110 to heat conducting parts of the fluid distributor 150 located upstream of the thermal insulation arrangement 215. Accordingly, the thermal insulation arrangement 215 enables different temperatures between the fluid distributor (upstream of the thermal insulation arrangement 215) and the reaction chamber 110 (downstream of the thermal insulation arrangement 215) as heat conductance from the reaction chamber 110 to the fluid distributor may be minimized.

Due to the thermal insulation arrangement 215, the fluid distributor 150, or at least the expansion region 210 of the fluid distributor 150, may advantageously be arranged to have lower temperature than the processing temperature within the reaction chamber 110 as heat transfer between the reaction chamber 110 and the fluid distributor 150 may be minimized. Therefore, premature thermal decomposition of precursors within the fluid distributor 150 may be minimized. Accordingly, thin-film quality and reaction chamber lifetime may be improved. Also, precursor consumption may be reduced. Furthermore, the thermal break between (the expansion region 210 of) the fluid distributor 150 and the reaction chamber 110 also allows for more flexibility in processing and chemistry selection. Also, higher reaction temperatures may be used within the reaction chamber which may improve deposition quality. In certain embodiments, the apparatus 100 comprising the thermal insulation arrangement 215 is used for thin-film deposition comprising TEMAZr or TEMAHf Precursors.

In certain embodiments, the fluid distributor 150 comprises a thermal insulation arrangement 215, shown in FIG. 2a, between the expansion region 210 and throat 220 of the fluid distributor 150. In certain embodiments, the thermal insulation arrangement 215 is a gasket. Advantageously, control of temperature conditions within the expansion region 210 and the reaction chamber 110 separately from each other and maintenance of their different temperature conditions may be improved.

In certain embodiments, the expansion region 210 comprises two opposite spreader regions 270a, 270b and a transition region 260, as shown in FIGS. 2b and 3b. The spreader regions 270a, 270b are sub-structures of the expansion region which enable expanding the reactant fluid flows F1, F2. The spreader regions 270a, 270b are separated from each other by the transition region 260. That is, the transition region 260 is located between the spreader regions 270a, 270b. The expanded reactant flows F1, F2 from the respective spreader regions 270a, 270b are combined with each other in the transition region 220.

In certain embodiments, the expansion region is configured to expand reactant fluid flows F1, F2 received from two gas inlets 155a, 155b to the spreader regions 270a, 270b laterally in a plane which is perpendicular to the flow direction through the reaction chamber 110, that is, perpendicular to the direction from the reaction chamber entrance 230 to the exhaust outlet 170. In certain embodiments, the expansion region 210 is configured to expand reactant fluid flows F1, F2 horizontally (i.e., in Z direction). In certain embodiments, the expansion region is configured to expand reactant fluid flows F1, F2 vertically (i.e., in Y direction). In certain embodiments, the expansion region is configured to expand the reactant fluid flows F1, F2 as fan-shaped flows. In certain embodiments, the expansion region is configured to expand the reactant fluid flows F1, F2 as laminar flows. In certain embodiments, the expansion region 210 is configured to expand reactant fluid flows F1, F2 to a width of the reaction chamber 110 (i.e., in Z direction). In certain embodiments, the expansion region 210 is configured to expand reactant fluid flows F1, F2 to a height of the reaction chamber 110 (i.e., in direction Y).

The transition region 260 is in connection to the throat 220. The throat 220 is further connected to the reaction chamber entrance 230 of the reaction chamber 110. That is, the throat 220 is configured to connect the fluid distributor 150 to the reaction chamber 110.

In certain embodiments, gas inlets 155a, 155b provide respective reactant fluid flows F1, F2 to respective spreader regions 270a, 270b of the fluid distributor 150 (i.e. one gas inlet in each spreader region). In certain embodiments, there is at least two gas inlets 155a, 155b. In certain embodiments, the gas inlets 155a, 155b are configured to feed reactant flows F1, F2 to the respective spreader regions 270a, 270b such that the fluid flows F1, F2 are forced to turn substantially 90 degrees after being fed to the respective spreader regions 270a, 270b. In certain embodiments, the gas inlets 155a, 155b are aligned perpendicularly to the fluid flow propagation direction within the respective spreader regions 270a, 270b. Advantageously, the reactant flows F1, F2 from the gas inlets 155a, 155b are configured to collide with the wall of the spreader region 270a, 270b which may further enhance fluid flow distribution within the expansion region 210.

The reactant fluid flows F1, F2 flow within the spreader regions 270a, 270b from the gas inlets 155a, 155b towards the transition region 260. That is, fluid flows F1, F2 from the opposite spreader regions 270a, 270b flow towards each other until the reactant fluid flows F1, F2 meet at the transition region 260. The reactant fluid flow F1, F2 direction within the spreader regions 270a, 270b is perpendicular to the laminar fluid flow LF direction (i.e., X direction) within the reaction chamber 110. In certain embodiments, the gas inlets 155a, 155 are configured to provide inert gas(es), for example, during purge, alternatively or additionally to the reaction precursors.

The reactant fluid flows F1, F2 are combined within the transition region 260 and subsequent throat 220 region to establish the laminar fluid flow LF. The laminar fluid flow LF is directed to the reaction chamber 110 from the throat 220 and through the reaction chamber entrance 230. The fluid distributor 150 is configured to turn the fluid flows F1, F2 from the spreader regions 270a, 270b 90 degrees within the transition region to propagate to the throat 220 and therefrom towards the reaction chamber 110 as the combined laminar flow LF. That is, the fluid flow direction in the spreader regions 270a, 270b is perpendicular to the general fluid flow direction (which is parallel to X axis) through the throat 220 towards the reaction chamber 110. Thus, the reactant fluid flows F1, F2 are redirected at the transition region 260.

In certain embodiments, the spreader regions 270a, 270b are triangle-shaped flat chambers (i.e. have triangular “bottom” and “top” walls). In certain embodiments, the triangle-shaped walls of the spreader regions 270a, 270b are flat and perpendicular to the direction of the laminar fluid flow LF (which is parallel to X axis) through the reaction chamber 110. In certain embodiments, the spreader regions 270a, 270b have a constant height (the opposite triangular “bottom” and “top” walls are parallel), wherein the height direction is parallel to the flow direction of the laminar fluid flow LF through the reaction chamber 110, i.e. X axis direction. In certain embodiments, the height of a spreader region is the distance between a first triangle shape wall and a second triangle shape wall of the spreader region 270a, 270b, which are positioned parallel and opposite to each other. The height of the spreader regions 270a, 270b is preferably limited to prevent turbulent fluid flow in said height direction. Advantageously, reactant fluid flows F1, F2 already within the spreader regions 270a, 270b towards the transition region 260 may be effectively propagated and expanded before their subsequent combination into the laminar flow LF.

In certain embodiments, the expansion region 210 comprises a cover which covers both opposite spreader regions 270a, 270b (replacing the “top” walls) and the rectangular transition region 260 in between. In certain embodiments, the cover is detachable. Note that the cover is excluded from FIGS. 2b and 3b to show the inside of the expansion region 210.

In certain embodiments, each spreader region 270a, 270b comprises a gas inlet connection, i.e., a point through which a gas inlet 155a, 155b is connected to provide fluid flow F1, F2 to the respective spreader regions 270a, 270b. In certain embodiments, the gas inlet 155a, 155b is connected to a corner of the triangle-shaped spreader region 270a, 270b which is furthest away from the transition region 260 Accordingly, a side of the triangle opposite to said corner is directed towards the transition region 260. In other words, in certain embodiments, reactant fluid flow F1, F2 direction within the spreader regions 270a, 270b is from a corner of the triangle (to which gas inlet 155a, 155b is connected) towards an opposing side of the triangle (which limits the transition region 260). In certain embodiments, the reactant fluid flow F1, F2 received from the gas inlet connection is forced to turn substantially 90 degrees towards the transition region 260 upon entrance to the spreader region 270a, 270b.

In certain embodiments, the expansion region 210 is configured to widen the reactant fluid flows F1, F2 (within the spreader regions 270a, 270b) laterally when progressing within the spreader regions 270a, 270b from the gas inlets 155a, 155b towards the transition region 260. In certain embodiments, widening (expanding) of the reactant fluid flows F1, F2 within the spreader regions 270a, 270b of the expansion region 210 is limited in height direction (Y direction) of the spreader regions 270a, 270b. In certain embodiments, the expansion region is configured to limit (or prevent) expanding of the reactant fluid flows F1, F2 within the expansion region 210 in the direction which is parallel to the direction of an axis of the reaction chamber 110 from the reaction chamber entrance 230 to the outlet opening 170, i.e. in X direction.

In certain embodiments, the lateral spreading direction within the expansion region 210 is perpendicular to the flow direction of the laminar fluid flow LF through the reaction chamber 110. In certain embodiments, the expansion region 210 is configured to expand the reactant fluid flows F1, F2 vertically (in Y direction). In certain embodiments, the expansion region 210 is configured to expand the reactant fluid flows F1, F2 horizontally (in Z direction). In certain embodiments, the expansion region 210 is configured to expand the reactant fluid flows F1, F2 as laminar flows within the fluid distributor 150. In certain embodiments, the expansion region 210 is configured to expand the reactant fluid flows F1, F2 in a plane which is perpendicular to the flow direction through the reaction chamber 110, that is, perpendicular to the direction from the reaction chamber entrance 230 to the exhaust outlet 170 (i.e., perpendicular to the X direction). Advantageously, laminar and lateral propagation of fluid flows F1, F2 within the spreader regions 270a, 270b may be enabled in certain embodiments. Further, fan-shaped distribution of reactant flows F1, F2 from the gas inlets 155a, 155b within the spreader regions 270a, 270b may be enabled already before reaching the reaction chamber 110.

In certain embodiments, the fluid distributor 150 is installed to the apparatus 110 in vertical configuration, as shown in FIGS. 1-2b. In the vertical configuration, the spreader regions 270a, 270b of the expansion region 210 are vertically separated (in Y direction) from each other by the transition region 220. Accordingly, the spreader regions 270a, 270b are configured to expand the reactant fluid flows F1, F2 from the gas inlets 155a, 155b horizontally (in Z direction) to the width of the reaction chamber 110 within the expansion region 210 while the fluid flows F1, F2 propagate vertically, as shown in FIG. 2b. In embodiments, where the fluid distributor 150 is in vertical configuration, the throat 220 comprises a constriction in vertical (Y) direction, as shown in FIG. 2a.

In certain other embodiments, the expansion region 210 is installed to the apparatus 110 in horizontal configuration, as shown in FIG. 3a-b. In the horizontal configuration, the spreader regions 270a, 270b are horizontally separated (in Z direction) from each other by the transition region 220. Accordingly, the spreader regions 270a, 270b are configured to expand the reactant fluid flows F1, F2 from the gas inlets 155a, 155b vertically (i.e., in Y direction to the height of the reaction chamber 110 within the expansion region 210 while the fluid flows propagate horizontally towards the transition region 260, as shown in FIG. 3b. In embodiments, where the fluid distributor 150 is in horizontal configuration, the throat 220 comprises a constriction in horizontal (Z) direction, according to embodiments shown in FIG. 3a. Note that in FIG. 3a the horizontal (Z) direction is towards the viewer and into the paper. Thus, only one of the gas inlets 155a, 155b is visible (one is behind the other) and the constriction of the throat is towards the viewer (for clarity, the fluid distributor of FIG. 3a can be taken to be like the fluid distributor of FIG. 2a but only rotated by 90 degrees around an axis (i.e. X axis) which is parallel to the direction of laminar fluid flow LF through the reaction chamber 110).

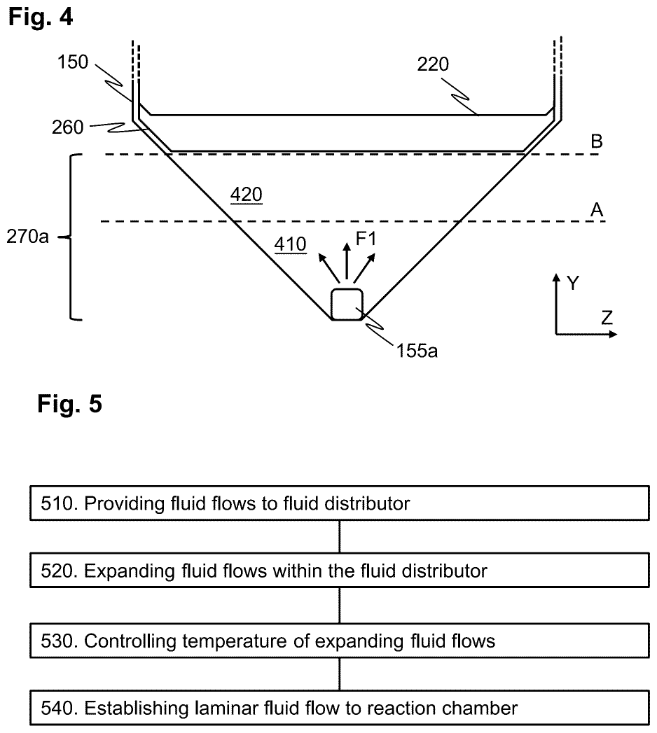

FIG. 4 schematically shows a part of an expansion region according to certain embodiments. Note that the part of the expansion region 210 shown in FIG. 4 is in vertical configuration, as shown, for example, in FIGS. 2a-2b. However, the expansion region could as well be in horizontal configuration as shown, for example, in FIGS. 3a-3b. In certain embodiments, the second expansion region 270b, opposite to the first expansion region 270a, is mirror image of the first expansion region 270a.

In certain embodiments, each spreader region 270a, 270b of the expansion region 210 comprises a first flow surface area 410 and a second flow surface area 420 on the inner surfaces (top, bottom and sides)) of the respective spreader regions 270a, 270b. In certain embodiments, the gas inlets 155a, 155b are configured to feed reactant fluid flows F1, F2 to the respective spreader regions 270a, 270b such that the respective fluid flow F1, F2 collides perpendicularly to the first flow surface area 410. That is, in certain embodiments, at least part of the first flow surface area 410 is located on the inner wall of a the spreader region 270a, 270b opposite to the gas inlet 155a, 155b providing fluid flow F1, F2 to that spreader region. 270a, 270b. In certain embodiments, the first flow surface area 410 begins from a gas inlet connection of the respective spreader region 270a, 270b and extends towards the transition region 260 of the fluid distributor 150. In certain embodiments, the first flow surface area 410 extends 5-10 cm downstream from the inlet connection, following the shape of the spreader region 270a, 270b.

In certain embodiments, the second flow surface area 420 is located downstream of the first flow surface area 410 and extends from the end of the first flow surface area 410 to the transition region 260. In FIG. 4, the transition from the first flow surface area 410 to the second flow surface area 420 is depicted with a dashed line A. Likewise, the transition from the second flow surface area 420 to the transition region 260 is depicted with a dashed line B. In certain embodiments, after the second flow surface area 420 (beyond the dashed line B in FIG. 4), the fluid distributor 150 is configured to start turning the reactant fluid flow F1 towards the throat 220 and the reaction chamber 110 within the transition region 260. From the transition region 260, the flow may proceed to the throat 220.

In certain embodiments, the first flow surface area 410 has a first surface roughness which is less than the second surface roughness of the second flow surface area 420. In certain embodiments, the second flow surface area (420) has a second surface roughness which is at least 30% higher than the first surface roughness of the first flow surface area (410). In certain embodiments, the first and second surface roughness are defined as roughness average (Ra) or root mean square (RMS) roughness of the respective surfaces. In certain embodiments, the second flow surface area 420 is manufactured by machining or treated after machining, for example, by abrasive blasting to achieve the second surface roughness. Advantageously, the low roughness of the first flow surface area 410 may enable minimizing the surface area where undesirable reversible adsorption-desorption of precursor fluid may take place in the first flow surface area. Therefore, more effective purging of physisorbed precursors from said area may be enabled. Furthermore, available and potentially reactive surface area near the near the gas inlet 155a, 155b connections may be minimized. Thus, undesired deposition within the expansion region 210 may be reduced.

In certain embodiments, the transition region 260 is limited and defined from opposite sides by one side of each triangle-shaped spreader region 270a, 270b (two corners and one side of each triangle defining also one side of the transition region 260, and one corner of each triangular spreader region 270a, 270b being directed away from the transition region 260 to opposite directions). In certain embodiments, the length of the side of each of the opposite spreader regions 270a, 270b limiting the transition region 260, is equal to the height of the reaction chamber 110 (in Y direction). In certain embodiments, the length of the side of each of the opposite spreader regions 270a, 270b limiting the transition region 260, is equal to the width of the reaction chamber 110 (in Z direction). Advantageously, the reactant fluid flows F1, F2 may already be expanded to the width or height of the reaction chamber 110 (i.e., in Z or Y direction, respectively) before reaching the reaction chamber entrance 230 depending on the orientation of the fluid distributor 150.

In certain embodiments, the transition region 260 is configured to turn the reactant flows F1, F2 from the spreader 270a, 270b 90 degrees towards the reaction chamber 100, i.e. from perpendicular flow direction to a flow direction which is parallel with the laminar flow LF direction through the reaction volume 115 (in X direction). In certain embodiments, the surfaces of the transition region 260 are configured to turn from the spreader regions 270a, 270b towards the narrowest point of the throat 220, i.e., be inclined or curved towards the reaction chamber 110. The transition region 260 is also configured to combine the opposite reactant flows F1, F2 together to proceed towards the reaction chamber 110 through the throat 220.

The throat 220 of the fluid distributor 150 is configured to connect the transition region 260 (and the entire fluid distributor 150) to the reaction chamber entrance 230. Fluid flow from the fluid distributor 150 is delivered to the reaction chamber entrance 230 through the throat 220, and therefrom further to the reaction volume 115 within the reaction chamber 110. In certain embodiments, the height of the throat 220 is equal to the height of the reaction chamber 110 (in Y direction) and comprises a constriction in lateral (horizontal) direction (in Z direction). In certain embodiments, the width of the throat 220 is equal to the width of the reaction chamber 110 (in Z direction) and comprises a constriction in vertical direction (Y direction). The constriction is the narrowest section of the throat 220. After the constriction, the throat 220 widens towards the reaction chamber entrance 230 to the dimensions of the reaction chamber entrance 230. In certain embodiments, the throat 220 is configured establish the laminar fluid flow LF from the fluid distributor 150 to the width and height of the reaction chamber 110 and to propagate through the reaction chamber 110.

In certain embodiments, the apparatus 100 comprises a cooler 160. In certain embodiments, the cooler 160 is coupled to the expansion region 210 of the fluid distributor 150. In certain embodiments, the cooler 160 attached to the outer surface of the expansion region 210 of the fluid distributor 150. In certain embodiments, the cooler 160 is attached to an outer surface of the expansion region 210 facing away from the reaction chamber 110. In certain embodiments, the cooler 160 is configured to control the temperature of the expansion region 210. In certain embodiments, the cooler 160 is configured to control the temperature of reactant fluid flow F1, F2 within the expansion region 210.

In certain embodiments, the apparatus comprises a controller 190 configured to control the temperature of the expansion region 210 (by controlling the cooler 160) separately from the temperature of the reaction chamber 110. In certain embodiments, the controller 190 comprises computing means, for example, a general-purpose computer, adapted to control the temperature of the expansion region 210 by controlling the cooler 160. In certain embodiments, the controller 190 comprises program code adapted to, when executed by the suitable computing means, control the temperature of the expansion region 210 by controlling the cooler. In certain embodiments, the controller 190 is adapted to also control the temperature of the reaction chamber 110.

Advantageously, stability of temperature sensitive reactants when using high deposition temperatures within the reaction chamber 110 may be improved by the cooler 160 through minimizing unwanted thermal decomposition. Thus, resource economy may be improved. The deposition temperature may be for instance from 200 °C to 350 °C for some processes. However, the skilled person understands that the relevant decomposition temperature(s) or temperature range(s) for each process depends on the selected precursor(s). Furthermore, the temperature of the reaction chamber 110 may be set higher without prematurely decomposing incoming fluid flows since the fluid distributor 150 temperature may be separately controlled by the cooler 160. Still further, the risk of reactant condensation within gas inlet pipes 155a, 155b may be avoided since cooling is not applied to the inlet pipes. Additionally, the width and high purge flow conditions of the expansion region 210, compared to inlet pipes, may further reduce the risk of reactant condensation within the expansion region 210.

For example, due to the cooler 160 controlling the temperature of the fluid distributor 150, decomposition of TEMAHf in the spreader regions 270a, 270b may be mitigated when using 200 °C deposition temperature in the reaction chamber 110, such that TEMAHf is able to survive to the substrate 120 surfaces despite the high deposition temperature. Such a high temperature is needed to achieve advantageous electrical properties, such as high-k value. Advantageously, high-k applications with a wider range of temperature sensitive precursors such as TEMAHf and TEMAZr may be enabled.

In certain embodiments, the cooler 160 comprises coolant liquid. In certain embodiments, the cooler 160 comprises metal block thermal well. In certain embodiments, the cooler 160 comprises Peltier element. In certain embodiments, the cooler 160 comprises water-cooling. In certain embodiments, the cooler 160 is a cooling system attached to a vacuum chamber 130 wall and connected to the expansion region 210 by cooling means. In certain embodiments, the cooler 160 is attached to the inner wall of the vacuum chamber 130, which at least partly surrounds the reaction chamber 110, and is connected to the expansion region 210 via cooling means. In certain embodiments, the connecting cooling means is a circulation system as shown in FIG. 1. In certain embodiments, the cooler 160 comprises circulation system, for example, coolant liquid circulation, connected to the expansion region 210, such as water cooling. Advantageously, efficient temperature control of expansion region may be achieved. Advantageously, in certain embodiments, the main cooler body does not need to be directly attached to the expansion region since the circulation allows flexibility in positioning the cooler 160.

In certain embodiments, the apparatus 100 comprises a vacuum chamber 130 (outer chamber, external chamber) 130. In certain embodiments, the vacuum chamber 130 (fully) encloses the reaction chamber 110. In certain embodiments, the vacuum chamber 130 at least partially surrounds the reaction chamber 110. In certain embodiments, the vacuum chamber 130 (fully) encloses the reaction chamber 110 and the fluid distributor 150. In certain embodiments, the vacuum chamber 130 at least partially surrounds the reaction chamber 110 and the fluid distributor 150. An intermediate space 135 is formed between the outside walls of the reaction chamber 110 and the inside walls of the vacuum chamber 130. The intermediate space 135 may be maintained under vacuum.

In certain embodiments, the vacuum chamber 130 comprises a loading opening 140 loading and unloading substrates or a stack of substrates to and from the vacuum chamber 130. In certain embodiments, the loading opening 140 comprises a closable door or lid. In certain embodiments, the substrates 120 are loaded to and unloaded from the substrate transfer system 240 within the vacuum chamber 130. In certain embodiments, a loading robot 250 performs the loading and/or unloading through the loading opening 140.

In certain embodiments, one or more heat reflectors 180 are located within the intermediate space 135. In certain embodiments, the inner side of the vacuum chamber 130 facing the fluid distributor 150 does not comprise heat reflectors 180. That is, in certain embodiments, the inner side of the vacuum chamber 130 facing the cooler 160 is free from heat reflector plates 180. In certain embodiments, the heat reflectors 180 surround the reaction chamber 110 and the fluid distributor 150 apart from the direction wherein the cooler 160 is located. Advantageously, heat dissipation by radiation from the cooler 160 away from the fluid distributor 150 (and reaction chamber 110) may be improved.

In certain embodiments, the one or more heat reflectors 180 comprise openable section(s), such as depicted with a dashed line in FIG. 1. In certain embodiment, such openable section(s) are integrated to and movable with the door 125 of the reaction chamber 110, substrate transfer system 240 and/or the loading opening 140 door of the vacuum chamber 130. This is to, for example, enable opening of the door 125 of the reaction chamber 110 and loading and unloading of the substrates to and from the reaction chamber 110. Advantageously, substrate loading and unloading may be facilitated as the heat reflector(s) 180 do not need to be dismantled.

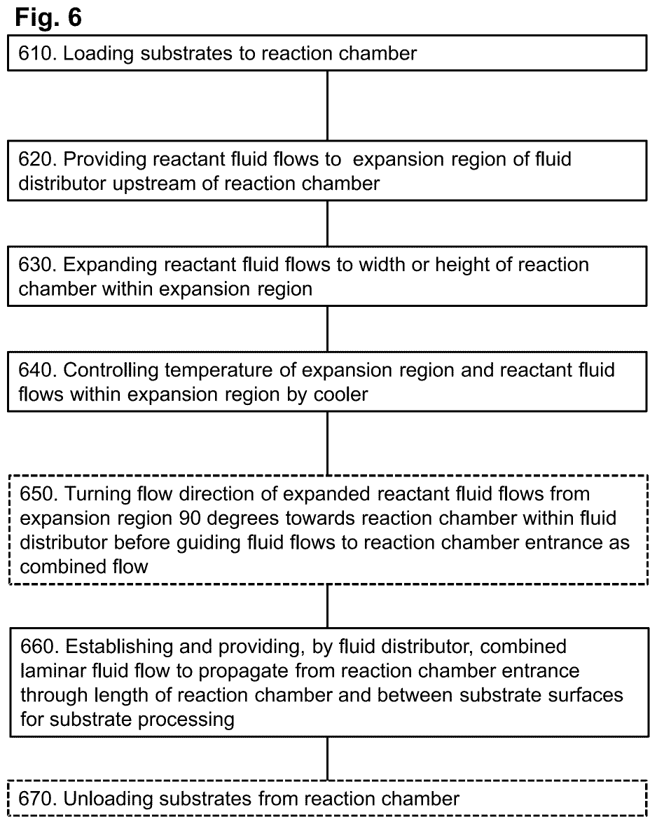

FIGS. 5 and 6 show flow charts of methods according to certain embodiments. Optional steps are marked with dashed boxes. The illustrated processes comprise various possible steps including some optional steps while also further steps can be included and/or some of the steps can be performed more than once. The processes may be implemented, for example, in the thin-film deposition apparatuses 100 of FIGS. 1-3b. Structural details of the apparatuses 100 have been provided in the foregoing with respect to FIGS. 1-4 and thus will not be repeated below.

The method of FIG. 5 comprises:
510: Providing reactant fluid flows F1, F2 to a fluid distributor. In certain embodiments, the method comprises providing the reactant fluid flows F1, F2 via gas inlets 155a, 155b. In certain embodiments, method comprises providing the reactant fluid flows F1, F2 to respective spreader regions 270a, 270b. In certain embodiments, providing reactant fluid flows (F1, F2) comprises providing flows of temperature sensitive precursor or precursors. In certain embodiments, the reactant fluid flows F1, F2 comprise sensitive precursors, such as TEMAHf and TEMAZr.
520: Expanding reactant fluid flows F1, F2 within the fluid distributor 150. The fluid distributor 150 is positioned upstream of the reaction chamber 110. In certain embodiments, the method comprises laterally expanding the reactant fluid flows F1, F2 within the expansion region 210 of the fluid distributor 150. In certain embodiments, the method comprises limiting the expansion of the reactant fluid flows F1, F2 within the expansion region 210 in the (expansion region's height) direction parallel to the reaction chamber axis (in X direction) from the reaction chamber entrance 230 to the exhaust outlet 170. In certain embodiments, the method comprises expanding the reactant fluid flows F1, F2 horizontally (in Z direction) or vertically (in Y direction) within the expansion region 210 while the fluid flows F1, F2 propagate towards the transition region 260. In certain embodiments, the method comprises expanding the reactant fluid flows F1, F2 as laminar flow within (the expansion region 210 of) the fluid distributor 150. In certain embodiments, the method comprises expanding the reactant fluid flows F1, F2 as laminar flow within the expansion region 210 of the fluid distributor 150 to the width (in Z direction) or height (in Y direction) of the reaction chamber 110. In certain embodiments, expanding fluid flows F1, F2 within the fluid distributor, comprises low roughness areas 410 within the expansion regions 270a, 270b (to minimize undesired reversible adsorption-desorption of the precursor to the fluid distributor 150 inner walls).
530: Controlling temperature of the expanding reactant fluid flows F1, F2 within (the expansion region 210 of) the fluid distributor 150. In certain embodiments, the method comprises controlling the temperature of the expansion region 210 of the fluid distributor 150. In certain embodiments, the temperature is controlled by the cooler 160. In certain embodiments, the cooler is coupled to the expansion region. In certain embodiments, the cooler is attached to outer surface of the expansion region.

In certain embodiments, the cooler 160 comprises coolant liquid, for example as oil with low vapor pressure. In certain embodiments, the cooler 160 comprises a metal block as a thermal wall and connected to the wall of the expansion region 210. In certain embodiments, the cooler 160 comprises a Peltier element connected to the fluid distributor 150. In certain embodiments, the cooler 160 comprises water cooling adapted to the outer chamber 130 wall and connected to the fluid distributor 150. In certain embodiments, the temperature of the expansion region 210 is controlled independently of the reaction chamber 110. In certain embodiments, controlling the temperature comprises removing heat reflectors from the outer chamber 130 directly facing the cooler 160 (to increase cooling efficiency through radiation).
540: Establishing laminar fluid flow LF to (and through) the reaction chamber 110 by the fluid distributor 150. In certain embodiments, establishing laminar fluid flow LF comprises combining first reactant fluid flow F1 and second reactant fluid flow F2 to form the laminar fluid flow LF. In certain embodiments, the fluid distributor 150 is configured to convert the reactant fluid flows F1, F2 provided by the gas inlets 155a, 155b to a laminar fluid flow LF to propagate through the reaction chamber 110. Advantageously, laminar flow formation may be facilitated by the fluid expansion within the expansion region 210.

The method of FIG. 6 comprises:
610: Loading substrates 120 to the reaction chamber 110. In certain embodiments, loading comprises loading a stack of substrates 120. In certain embodiments, the method comprises loading the substrates 120 to the substrate transfer system 240 within the vacuum chamber 130 by a loading robot 250. The substrates 120 may be loaded individually or as a stack. The substrate loading system 240 is configured to transfer the substrates 120 into the reaction chamber 110. The substrates 120 may be, for example, circular wafers.
620: Providing reactant fluid flows F1, F2 to an expansion region 210 of a fluid distributor 150 upstream of a reaction chamber 110. In certain embodiments, the method comprises providing reactant fluid flows F1, F2 from at least two gas inlets 155a, 155b. In certain embodiments, the method comprises providing reactant fluid flows F1, F2 to respective spreader regions 270a, 270b of the expansion region 210. In certain embodiments, the expansion region 210 comprises two opposite spreader regions 270a, 270b. In certain embodiments, the reactant fluid flows F1, F2 are configured to propagate essentially towards each other (and towards the transition region 260) within the respective spreader regions 270a, 270b. In certain embodiments, providing reactant fluid flows (F1, F2) comprises providing flows of temperature sensitive precursor or precursors.
630: Expanding the reactant fluid flows F1, F2 laterally within the expansion region 210. In certain embodiments, the method comprises, expanding the reactant fluid flows F1, F2 to the width or height of the reaction chamber 210 within the expansion region 210. In certain embodiments, the method comprises laterally expanding the reactant fluid flows F1, F2 within the expansion region 210 of the fluid distributor 150 while the fluid flows F1, F2 propagate towards the transition region 260. In certain embodiments, the method comprises limiting the expansion of the reactant fluid flows F1, F2 within the expansion region 210 in the direction parallel to the reaction chamber axis from the reaction chamber entrance 230 to the exhaust outlet 170 (i.e., in height direction of the expansion region 210 which is parallel to X axis direction). In certain embodiments, the method comprises expanding the reactant fluid flows F1, F2 horizontally (in Z direction) or vertically (in Y direction) within the expansion region 210. In certain embodiments, the method comprises expanding the reactant fluid flows F1, F2 as laminar flow within (the expansion region 210 of) the fluid distributor 150.
640: Controlling temperature of the expansion region and the reactant fluid flows F1, F2 within the expansion region by a cooler 160. In certain embodiments, the cooler 160 is coupled to the expansion region. In certain embodiments, the cooler 160 attached to the outer surface of the expansion region 210. In certain embodiments, the cooler 160 attached to the wall of the vacuum chamber 130 and connected to the outer surface of the expansion region 210 via cooling means, for example, via a water-cooling circulation system. Advantageously, the cooler may effectively control the temperature of the expansion region and the expanding fluid flows F1, F2 within the expansion region 210.

In certain embodiments, the cooler 160 comprises coolant liquid, for example as oil with low vapor pressure. In certain embodiments, the cooler 160 comprises a metal block as a thermal wall and connected to the wall of the expansion region 210. In certain embodiments, the cooler 160 comprises a Peltier element connected to the fluid distributor 150. In certain embodiments, the cooler 160 comprises water cooling adapted to the outer chamber 130 wall and connected to the fluid distributor 150. In certain embodiments, the temperature of the expansion region 210 is controlled independently of the reaction chamber 110. In certain embodiments, controlling the temperature comprises removing heat reflectors from the outer chamber 130 directly facing the cooler 160 (to increase cooling efficiency through radiation).
650: Turning the flow direction of the expanded fluid flows F1, F2 from the expansion region 210 90 degrees towards the reaction chamber within the fluid distributor 150 before guiding the fluid flows F1, F2 to the reaction chamber entrance 230 as a combined flow.
660: Establishing and providing, by the fluid distributor 150, a combined laminar fluid flow LF to propagate from a reaction chamber entrance 230 through the length of the reaction chamber 110 and between the substrate surfaces for substrate processing.
670: Unloading the substrates 120 from the reaction chamber 110.

Without limiting the scope and interpretation of the patent claims, certain technical effects of one or more of the example embodiments disclosed herein are listed in the following. A technical effect is improved reactant temperature control and cooling upstream of reaction chamber. Another technical effect is improving use and processing quality with temperature sensitive reactants. Another technical effect is reducing premature decomposition of temperature sensitive precursors when using high deposition temperatures. Another technical effect is enabling use of high deposition temperatures, such as 200 °C and above, with temperature sensitive reactants that are prone to decomposition at high temperatures. Still another technical effect is reducing waste of resources, particularly of temperature sensitive reactants. A further technical effect is enabling cooling of reactant flow while mitigating reactant condensation and gas inlet contamination.

Various embodiments have been presented. It should be appreciated that in this document, words comprise, include, and contain are each used as open-ended expressions with no intended exclusivity.

The foregoing description has provided by way of non-limiting examples of particular implementations and embodiments a full and informative description of the best mode presently contemplated by the inventors for carrying out the invention. It is however clear to a person skilled in the art that the invention is not restricted to details of the embodiments presented in the foregoing, but that it can be implemented in other embodiments using equivalent means or in different combinations of embodiments without deviating from the characteristics of the invention.

Furthermore, some of the features of the afore-disclosed example embodiments may be used to advantage without the corresponding use of other features. As such, the foregoing description shall be considered as merely illustrative of the principles of the present invention, and not in limitation thereof. Hence, the scope of the invention is only restricted by the appended patent claims.

1. A thin-film deposition apparatus comprising:
a reaction chamber for accommodating a stack of substrates arranged with their planar surfaces facing each other;
a fluid distributor for establishing a laminar fluid flow, by combining first reactant fluid flow and second reactant fluid flow, to propagate from a reaction chamber entrance through the length of the reaction chamber and between the substrate surfaces, wherein the fluid distributor comprises an expansion region configured to laterally expand the reactant fluid flows before forming the laminar fluid flow; and
a cooler coupled to the expansion region and configured to control the temperature of the expansion region.

2. The thin-film deposition apparatus of claim 1, wherein the cooler comprises coolant liquid, metal block thermal well, or Peltier element.

3. The thin-film deposition apparatus of claim 1, wherein the apparatus comprises a controller configured to control the temperature of the expansion region separately from the temperature of the reaction chamber.

4. The thin-film deposition apparatus of claim 1, wherein the expansion region comprises two opposite triangle-shaped spreader regions, wherefrom the respective fluid flows are directed towards the reaction chamber entrance as a combined flow through a throat of the fluid distributor.

5. The thin-film deposition apparatus of claim 4, wherein each spreader region comprises a first flow surface area and a second surface area on the inner surfaces of the respective spreader regions, wherein the first flow surface area extends from a gas inlet connection of the respective spreader region towards a transition region of the fluid distributor following the shape of the spreader region, and wherein the second flow surface area is located downstream of the first flow surface area extends from the end of the first flow surface area to the transition region.

6. The thin-film deposition apparatus of claim 5, wherein the first flow surface area has a first surface roughness and the second flow surface area has a second surface roughness, and wherein the first surface roughness is lower than the second surface roughness.

7. The thin-film deposition apparatus of claim 4, wherein the fluid distributor comprises a thermal insulation arrangement between the expansion region and throat of the fluid distributor.

8. The thin-film deposition apparatus of claim 4, wherein the fluid distributor is configured to turn the flow direction of the reactant fluid flows from the spreader regions 90 degrees to redirect them towards the throat and reaction chamber entrance.

9. The thin-film deposition apparatus of claim 1, comprising a vacuum chamber at least partially surrounding the reaction chamber and the fluid distributor.

10. The thin-film deposition apparatus of claim 9, wherein the inner side of the vacuum chamber facing the cooler located on an outer surface of the fluid distributor is free from heat reflector plates.

11. The thin-film deposition apparatus of claim 9, wherein the cooler is attached to the vacuum chamber wall and connected to the expansion region via cooling means.

12. The thin-film deposition apparatus of claim 1, comprising a thermal insulation arrangement located between the expansion region of the fluid distributor and the reaction chamber.

13. A method for thin-film deposition, comprising:
loading a stack of substrates to a reaction chamber;
providing first reactant fluid flow and second reactant fluid flow to an expansion region of a fluid distributor upstream of a reaction chamber;
expanding said reactant fluid flows laterally within the expansion region;
controlling temperature of the expansion region and the reactant fluid flows within the expansion region by a cooler which is coupled to the expansion region; and
establishing a laminar fluid flow, by combining said reactant fluid flows, by the fluid distributor, to propagate from a reaction chamber entrance through the length of the reaction chamber and between the substrate surfaces for substrate processing.

14. The method of claim 13, wherein the cooler comprises coolant liquid, metal block thermal well, or Peltier element.

15. The method of claim 13, further comprising:
controlling the temperature of the expansion region separately from the temperature of the reaction chamber.

16. The method of claim 13, wherein said reactant fluid flows comprise temperature sensitive precursor or precursors.

17. The method of claim 13, comprising:
processing the stack of substrates with alternating self-limiting surface reactions.
